(19) United States
(12) Patent Application Publication
(10) Pub. No.: US 2026/0123405 A1
(43) Pub. Date: Apr. 30, 2026

(54) INTEGRATED CIRCUIT DIE STACK WITH HEAT DISSIPATION ENHANCEMENT STRUCTURES

(71) Applicant: Taiwan Semiconductor Manufacturing Company, Ltd., Hsinchu (TW)

(72) Inventors: Chieh-Lung LAI, Taichung City (TW); Meng-Liang LIN, Hsinchu (TW); Hsien-Wei CHEN, Hsinchu City (TW); Kathy Wei YAN, Hsinchu (TW)

(73) Assignee: Taiwan Semiconductor Manufacturing Company, Ltd., Hsinchu (TW)

(21) Appl. No.: 18/928,888

(22) Filed: Oct. 28, 2024

(51) Int. Cl. H01L 23/367; H01L 21/48; H01L 21/56; H01L 23/00; H01L 23/31; H01L 23/373; H01L 25/00; H01L 25/065

(52) U.S. Cl. CPC H10W 40/22; H10W 40/258; H10W 70/023; H10W 74/016; H10W 74/121; H10W 90/00; H10W 72/07652; H10W 72/621; H10W 72/862; H10W 90/20; H10W 90/288; H10W 90/297; H10W 90/722; H10W 90/724; H10W 90/762

(57) ABSTRACT

A die stack structure is provided. The die stack structure includes a non-extended semiconductor die, an extended semiconductor die, and an extended top semiconductor die are stacked vertically over a base semiconductor die. The extended semiconductor die and the extended top semiconductor die each have an extension portion extending horizontally outward from one side thereof as compared to the non-extended semiconductor die. An encapsulant layer is formed over the base semiconductor die and encapsulates the sidewalls of the non-extended semiconductor die, the extended semiconductor die, and the extended top semiconductor die. Thermally conductive features are formed in the extension portion of the extended semiconductor die and in the extension portion of extended top semiconductor die. A thermally conductive structure is embedded in the encapsulant layer, extending vertically between the extended semiconductor die and the extended top semiconductor die, and contacting the thermally conductive features.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

As semiconductor technologies further advance, stacked semiconductor devices, e.g., three dimensional integrated circuits (3DIC), have emerged as an effective alternative to further reduce the physical size of a semiconductor device. In a stacked semiconductor device, active circuits such as logic, memory, processor circuits and the like are fabricated on different semiconductor wafers. Two or more package components (e.g., semiconductor wafers, dies or chips, interposers, etc.) may be stacked on top of one another to further reduce the form factor of the semiconductor device.

Although existing 3D packaging technologies for fabricating 3DIC devices have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit (IC) package, in accordance with some embodiments.

FIG. 2 is a cross-sectional view of a die stack with additional heat dissipation enhancement structures, in accordance with some embodiments.

FIG. 3 is a top view of the die stack shown in FIG. 2, in accordance with some embodiments, showing the extended topmost semiconductor die of the die stack and thermally conductive features therein.

FIGS. 4A and 4B are top views of the die stack shown in FIG. 2, in accordance with some alternative embodiments, showing the extended topmost semiconductor die of the die stack and thermally conductive feature(s) therein.

FIG. 5 is a plan view taken along line A-A in FIG. 2, in accordance with some embodiments.

FIGS. 6 to 10 illustrate cross-sectional views of intermediate steps of forming the die stack shown in FIG. 2, in accordance with some embodiments.

FIG. 11 is a cross-sectional view of an integrated circuit (IC) package including the die stack shown in FIG. 2, in accordance with some embodiments.

FIG. 12 is a cross-sectional view of a die stack with additional heat dissipation enhancement structures, in accordance with some embodiments.

FIG. 13 is a cross-sectional view of a die stack with additional heat dissipation enhancement structures, in accordance with some embodiments.

FIG. 14 is a cross-sectional view of a die stack with additional heat dissipation enhancement structures, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A three dimensional integrated circuits (3DIC) structure (e.g., IC die stack) and the method of forming the same are provided in accordance with some embodiments of the present disclosure. A die stack may include a plurality of semiconductor dies stacked on each other and an encapsulant layer that encapsulates and protects these semiconductor dies. According to various embodiments, additional heat dissipation enhancement structures are placed or formed in the side areas originally occupied by the encapsulant layer to provide additional thermal path in the die stack structure, thereby increasing the heat dissipation efficiency of the entire structure. As a result, the performance of the die stack is improved. Details of the heat dissipation enhancement structures and some variations of some embodiments are described below.

The Embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

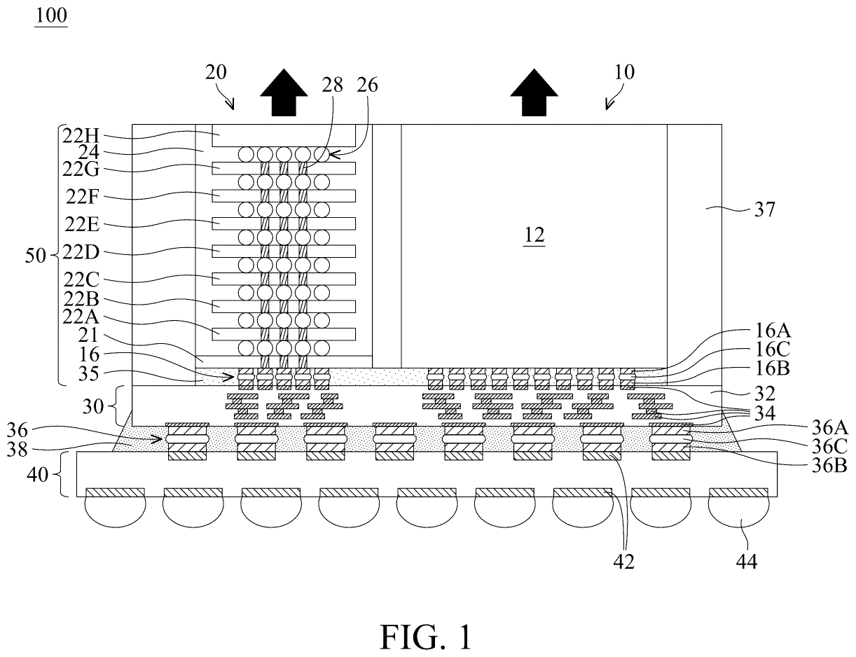

First, referring to FIG. 1, which is a cross-sectional view of an integrated circuit (IC) package 100 in accordance with some embodiments. The IC package 100 may be a 3DIC package (e.g., a chip-on-wafer-on-substrate (CoWoS) package), which may include at least one integrated circuit (IC) die 10, at least one (IC) die stack 20, an interposer 30, and a package substrate 40. It should be understood that the number of IC die 10 and die stack 20 included in the IC package 100 shown in FIG. 1 is for illustration only, and the disclosure is not limited thereto. Additional components or devices can also be added to the IC package 100 in other embodiments. Some of the features described below can be replaced or eliminated for different embodiments.

In some embodiments, the IC die 10 and the die stack 20 is bonded over the interposer 30, as shown in FIG. 1. In some embodiments, the IC die 10 may have the same or a different dimension (e.g., larger) vertical height than the die stack 20. Each of the IC die 10 and the die stack 20 may have a square or rectangle cross-sectional shape in plan view (e.g., top view).

In some embodiments, the IC die 10 includes a semiconductor substrate 12 (e.g., silicon substrate) and an interconnection structure (not shown) formed on the semiconductor substrate 12. For example, the interconnection structure is formed on the bottom surface of the semiconductor substrate 100. The interconnection structure includes multiple dielectric layers and multiple electrically conductive features formed in the dielectric layers. These electrically conductive features include conductive lines, conductive vias, and conductive contacts. Some portions of the conductive features may be used as conductive pads.

In some embodiments, various device elements (not shown) are formed in and/or on the semiconductor substrate 12. Examples of the device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or other suitable elements. The device elements are interconnected through the interconnection structure to form integrated circuit devices. The integrated circuit devices may include logic devices (e.g., central processing unit (CPU) devices, graphic processing unit (GPU) devices, application specific integrated circuit (ASIC) devices, field programmable gate array (FPGA) devices, or the like), memory devices (e.g., static random access memory (SRAM) devices, dynamic random access memory (DRAM) devices, or the like), radio frequency (RF) devices, input/output (I/O) devices, system-on-chip (SoC) devices, other applicable types of devices, or a combination thereof. In some embodiments, the IC die 10 is a system-on-chip (SoC) device that includes multiple functions.

In some embodiments, the die stack 20 includes multiple semiconductor dies 21, 22A, 22B, 22C, 22D, 22E, 22F, 22G, and 22H stacked on top of each other, as shown in FIG. 1. In some embodiments, the die stack 20 includes an encapsulant layer 24 that encapsulates and protects these semiconductor dies. The encapsulant layer 24 may include molding compound, molding underfill, epoxy, resin, and/or the like.

In some embodiments, the semiconductor dies 22A, 22B, 22C, 22D, 22E, 22F, 22G, and 22H are memory dies, such as static random access memory (SRAM) dies, dynamic random access memory (DRAM) dies, other suitable memory dies, or a combination thereof. In some embodiments, the bottommost semiconductor die 21 (also called a base semiconductor die 21) is a control die that is electrically connected to the memory dies (e.g., 22A-22H) stacked thereon. The die stack 20 may function as a high bandwidth memory (HBM) controlled by the control die (e.g., 21).

In some embodiments, the semiconductor dies 21 and 22A-22H may have similar structures. In some embodiments, each of the semiconductor dies 21 and 22A-22H has a structure that is similar to the IC die 10 described above. For example, each of these semiconductor dies may include a semiconductor substrate (e.g., silicon substrate), a plurality of devices (such as memory devices, which may include DRAM devices, SRAM devices, other suitable memory device, or a combination thereof) formed in and/or on the semiconductor substrate, and an interconnection structure formed on the semiconductor substrate. The interconnection structure includes multiple electrically conductive features formed in the dielectric layers, wherein the electrically conductive features electrically connect the memory devices to form a functional circuit. These electrically conductive features include conductive lines, conductive vias, and conductive contacts. Some portions of the conductive features may be used as conductive pads.

In some embodiments, electrically conductive bonding structures 26 are formed between the semiconductor dies 21, 22A, 22B, 22C, 22D, 22E, 22F, 22G, and 22H to bond them together, as shown in FIG. 1. In some embodiments, each of the electrically conductive bonding structures 26 may include metal pillars, solder bumps, or both. In some embodiments, the electrically conductive bonding structures 26 may be micro bumps.

In some embodiments, the die stack 20 includes optional underfill elements (not shown) formed between the semiconductor dies 21, 22A, 22B, 22C, 22D, 22E, 22F, 22G, and 22H to surround and protect the electrically conductive bonding structures 26. In some embodiments, the underfill elements are omitted, and the encapsulant layer 24 extends into the gaps between these semiconductor dies to directly contact the electrically conductive bonding structures 26.

In some embodiments, the encapsulant layer 24 encapsulates sidewalls of the semiconductor dies 22A-22H and sidewalls of the underfill elements (if present). In some embodiments, the bottom surface of the encapsulant layer 24 is substantially coplanar with the top surface of the bottommost semiconductor die 21. In some embodiments, the top surface of the encapsulant layer 24 is substantially coplanar with the top surface of the topmost semiconductor die 22H (also called top semiconductor die 22H) such that the top surface of the semiconductor die 22H is exposed.

In some embodiments, the encapsulant layer 24 may be formed by a molding process (e.g., transfer molding, compression molding, or the like) and a planarization process. For example, an encapsulant material layer is formed over the bottommost semiconductor die 21 to encapsulate sidewalls of the semiconductor dies 22A-22H and the top surface of the topmost semiconductor die 22H through a molding process. Thereafter, a planarization process, such as a chemical mechanical polishing (CMP) process, is performed to remove a portion of the encapsulant material layer over the top surface of the topmost semiconductor die 22H to expose the semiconductor die 22H, and form the encapsulant layer 24.

In some embodiments, electrically conductive features 28 are formed in some of the semiconductor dies in the die stack 20. As shown in FIG. 1, each of the electrically conductive features 28 vertically penetrates through one of the semiconductor dies 21, 22A, 22B, 22C, 22D, 22E, 22F, and 22G and is electrically connected to one of the conductive bonding structures 26. The electrically conductive features 28 are used as through substrate vias (TSVs). Electrical signals may be transmitted between these vertical stacked semiconductor dies through the electrically conductive features 28. In some embodiments, the topmost semiconductor die 22H is free of electrically conductive features 28 (e.g., TSVs). In alternative embodiments, electrically conductive features 28 may be formed in the topmost semiconductor die 22H, but are not revealed from the top surface of the semiconductor die 22H. The electrically conductive features 28 may include metal (e.g., copper) or metal alloys.

In some embodiments, the IC die 10 and the die stack 20 are bonded onto the interposer 30 through electrically conductive bonding structures 16, as shown in FIG. 1. In some embodiments, the electrically conductive bonding structures 16 include solder bumps, metal pillar bumps, other suitable structures, or a combination thereof. In some embodiments, each of the electrically conductive bonding structures 16 includes a metal pillar bump 16A, a metal pillar bump 16B, and a solder element 16C, as shown in FIG. 1. For example, the metal pillar bumps 16A and 16B are formed of copper.

In some embodiments, multiple metal pillar bumps 16A are formed over the bottom surfaces of the IC die 10 and the die stack 20 and are electrically coupled to their internal electrically conductive features. In some embodiments, multiple metal pillar bumps 16B are formed over the top surface of the interposer 30 before the bonding with the IC die 10 and the die stack 20 and are electrically coupled to its internal electrically conductive features. In some embodiments, solder material, such as solder paste, is applied on one or both of the metal pillar bumps 16A and 16B before the bonding process. Afterwards, by performing a high-temperature reflow process, the metal pillar bumps 16A and 16B are bonded together through the solder material. The solder material forms the solder element 16C between the metal pillar bumps 16A and 16B. As a result, the electrically conductive bonding structures 16 are formed.

In some embodiments, the interposer 30 is used to provide electrical connection between packaged components thereon (e.g., the IC die 10 and the die stack 20), and between these packaged components and a package substrate 40 bonded below the interposer 30. In some embodiments, the interposer 30 is a dielectric substrate that includes a redistribution line (RDL) structure. The RDL structure includes multiple dielectric layers 32 and multiple electrically conductive features 34 surrounded by the dielectric layers 32, as shown in FIG. 1. The electrically conductive features 34 include conductive lines providing electrical connection in horizontal directions, conductive vias providing electrical connection in vertical directions, and contact pads exposed at opposite outermost surfaces of the interposer 30 to allow external electrical connections. It should be understood that the configuration of the RDL structure shown in FIG. 1 is merely a schematic example, and is not intended to be, and should not be construed to be, limiting to the present disclosure.

In other embodiments, the interposer 30 may be a semiconductor substrate and may include electrically conductive features therein or thereon (e.g., conductive lines, conductive vias, TSVs, redistribution layers, metallization patterns, or the like) to provide the interconnection functions described above. Further details of the interposer 30 are not described here.

In some embodiments, an underfill element 35 is formed over the top surface of the interposer 30 to surround and protect the electrically conductive bonding structures 16, as shown in FIG. 1. In some embodiments, the underfill element 35 is in direct contact with the electrically conductive bonding structures 16. In some embodiments, a liquid underfill material is dispensed by capillary action and cured to form the underfill element 35. In some embodiments, the underfill element 35 includes an epoxy-based resin with fillers dispersed therein. The fillers may include insulating fibers, insulating particles, other suitable elements, or a combination thereof.

In some embodiments, a package layer 37 is formed over the top surface of the interposer 30 to encapsulate the IC die 10 and the die stack 20, as shown in FIG. 1. In some embodiments, the package layer 37 fills the gap between the IC die 10 and the die stack 20. In some embodiments, the package layer 37 is in direct contact with the underfill element 35. In some embodiments, the package layer 37 is not in direct contact with the electrically conductive bonding structures 16. In some embodiments, the package layer 37 is in direct contact with the encapsulant layer 24 of the die stack 20.

In some embodiments, the top surface of the package layer 37 is substantially coplanar with the top surfaces of the IC die 10 and the die stack 20 such that the top surfaces of the IC die 10 and the die stack 20 are exposed. In some embodiments, one of the IC die 10 and the die stack 20 may be buried within the package layer 37 and not exposed. The material and formation method of the package layer 37 may be similar to the material and formation method of the encapsulant layer 24 described above.

For purposes of illustration, the combination of the interposer 30 and the various components thereon (e.g., the IC die 10, die stack 20, and the package layer 37) are collectively referred to hereinafter as a chip-on-wafer (CoW) packaging component 50.

In some embodiments, the CoW packaging component 50 is bonded onto the package substrate 40 through electrically conductive bonding structures 36, as shown in FIG. 1. In some embodiments, the electrically conductive bonding structures 36 include solder bumps, metal pillar bumps, other suitable structures, or a combination thereof. In some embodiments, each of the electrically conductive bonding structures 36 includes a metal pillar bump 36A, a metal pillar bump 36B, and a solder element 36C, as shown in FIG. 1. The materials and formation methods of the electrically conductive bonding structures 36 may be similar to the materials and formation methods of the electrically conductive bonding structures 16 described above.

In some embodiments, an underfill element 38 is formed over the top surface of the package substrate 40 to surround and protect the electrically conductive bonding structures 36, as shown in FIG. 1. The material and formation method of the underfill element 38 may be similar to the material and formation method of the underfill element 35 described above.

In some embodiments, the package substrate 40 is used to provide electrical connection between devices or dies packaged in the package structure (e.g., the CoW packing component 50) and an external electronic device. Although not shown, the package substrate 40 includes electrically conductive features (e.g., conductive lines and conductive vias) to interconnect contact pads 42 exposed at opposite outermost surfaces of the package substrate 40. The package substrate 40 may be a cored or coreless substrate. In some embodiments, the package substrate 40 may be a printed circuit board (PCB), a ceramic substrate, or another suitable package substrate. In some embodiments, multiple electrically conductive structures 44, such as solder balls, are formed on the bottom surface of the package substrate 40 to provide external electrical connection.

In some embodiments, a package lid (for simplicity, not shown) may also be disposed over the top surface of the CoW packaging component 50. In some embodiments, the package lid laterally surrounds the sidewalls of the CoW packaging component 50 such that the CoW packaging component 50 is fully-enclosed by the combination of the package substrate 40 and the package lid. In some embodiments, the package lid is attached to the top surface of the package substrate 40 via adhesive, and may be used to reduce warpage of the package substrate 40.

In some embodiments, the package lid includes a suitable thermally conductive material, such as a metal (e.g., copper) or a metal alloy, and is also attached to the top surface of the CoW packaging component 50 (e.g., the top surfaces of the IC die 10 and the die stack 20) through a thermal interface material (TIM). In such embodiments, the package lid also helps dissipate heat generated from the IC die 10 and the die stack 20, as indicated by the upward arrows in FIG. 1.

In some embodiments, a heat sink (for simplicity, not specifically shown) is also provided on the top surface of the package lid to improve heat dissipation efficiency. The heat sink may include fins or other features that may be configured to increase a surface area between the heat sink and a cooling fluid, such as ambient air. In some embodiments, the heat sink may be a separate component from the package lid or may be integrally formed with the package lid.

It should be understood that as the functions of electronic products become more and more complex, the number of stacked semiconductor dies in the die stack (e.g., 20) also increases. This results in that some lower semiconductor dies may not be able to effectively dissipate heat, such as through the aforementioned heat dissipation devices located above the topmost semiconductor die (e.g., 22H) (e.g., the TIM, package lid, and the heat sink). Without removal of the heat, there may be thermal impacts on the IC performance or reliability. Therefore, a solution is needed to avoid heat accumulation in the die stack structure.

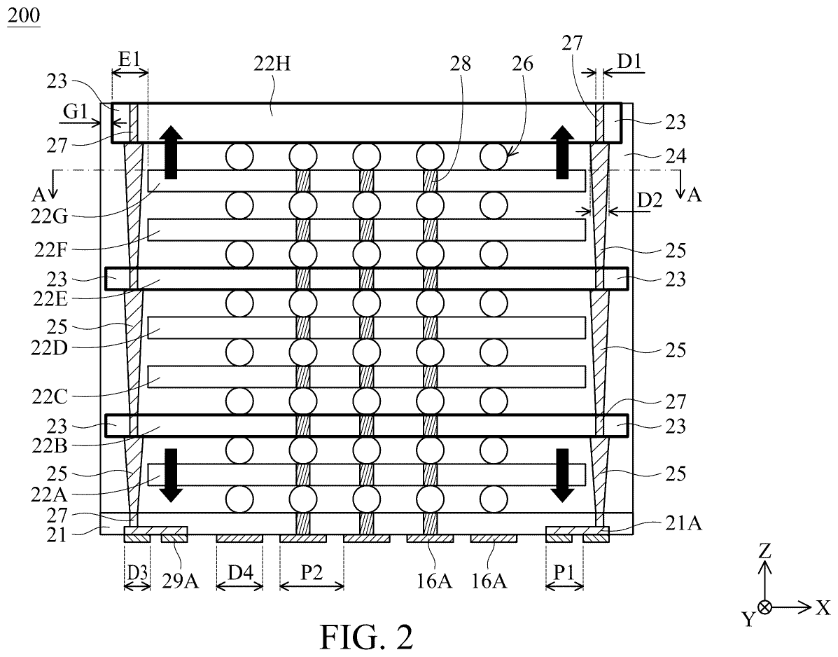

Referring to FIG. 2, which is a cross-sectional view of a die stack 200 with additional heat dissipation enhancement structures that help address the above issues, in accordance with some embodiments. The structure of the die stack 200 is similar to the structure of the die stack 20 in FIG. 1 above, so only the differences (i.e., additional heat dissipation enhancement structures) will be described below.

In some embodiments, some semiconductor dies (e.g., 22H, 22E, and 22B) in the die stack 200 are extended or enlarged in size (these semiconductor dies are therefore referred to below as extended semiconductor dies), while other semiconductor dies (e.g., 22G, 22F, 22D, 22C, 22A, and 21) remain the same size (these semiconductor dies are therefore referred to below as non-extended semiconductor dies), as shown in FIG. 2. In some embodiments, each extended semiconductor die 22H, 22E, or 22B has one or more extension portions 23 extending horizontally (e.g., in the X-Y plane) and outwardly from one or more sides thereof, so that the outer edges (i.e., sidewalls) of these extended semiconductor dies (e.g., the extension portions 23) are closer to the outer edges (i.e., sidewalls) of the encapsulant layer 24 than the outer edges (i.e., sidewalls) of the non-extended semiconductor dies. These extension portions 23 are used to place thermally conductive features (e.g., 27) that are described below.

In some embodiments, no integrated circuit devices or electrically conductive features are provided in the extension portions 23, so they are also called dummy areas. For example, each extension portion 23 (dummy area) extends outwardly from an outer edge of a functional (or active) area (not shown) of the respective semiconductor die (e.g., 22H, 22E, or 22B) in which the integrated circuit devices are formed in. In some embodiments, these extended semiconductor dies with one or more extension portions can be obtained (e.g., after singulation) by providing one or more dummy areas between the functional area and adjacent scribe line(s) of each semiconductor die during the wafer fabrication stage. In other words, the pre-formed dummy area(s) near the outer edge(s) of each semiconductor die forms the extension portion(s) of the extended semiconductor dies after singulation.

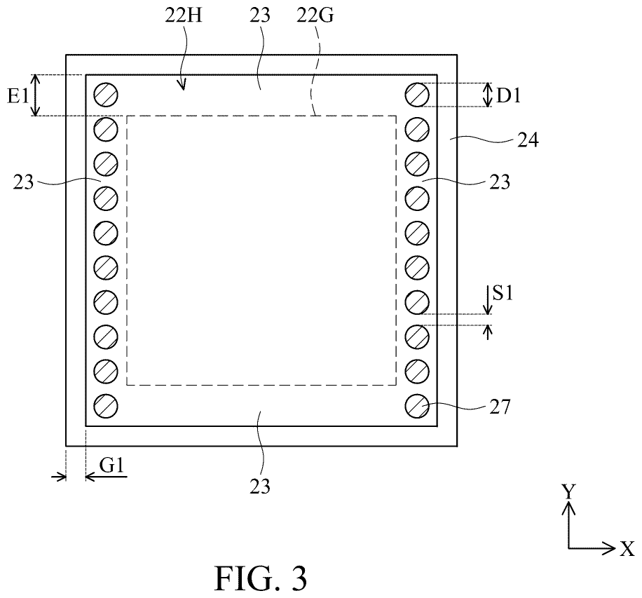

In some embodiments, each extended semiconductor die 22H, 22E, or 22B has multiple (e.g., four) extension portions 23 extending horizontally and outward from all (e.g., four) sides thereof. For example, referring to FIG. 3, which is a top view of the die stack 200 shown in FIG. 2 in accordance with some embodiments, wherein the extended topmost semiconductor die 22H is shown as having four extension portions 23 extending horizontally and outwardly from its four sides. As such, the four extension portions 23 are collectively in an annular shape. It should be noted that a lower non-extended semiconductor die 22G is also shown in FIG. 3 (depicted in dashed lines) for comparison. The extension portions 23 of the extended semiconductor dies 22E and 22B may have a similar shape (i.e., annular shape) as the extension portions 23 of the extended topmost semiconductor die 22H, and thus are not separately shown.

In some embodiments, the extension portions 23 of each extended semiconductor die 22H, 22E, or 22B have the same width (i.e., extended width E1) around its periphery, although the disclosure is not limited thereto. The extended width E1 of each extension portion 23 can be measured between its outer edge (i.e., sidewall) and the outer edge (i.e., sidewall) of the adjacent non-extended semiconductor die, as shown in FIG. 3. In some embodiments, the extended width E1 is greater than or equal to about 50 μm to accommodate thermally conductive features (e.g., 27) of sufficient size. In some embodiments, a gap size G1 between the outer edge (i.e., sidewall) of each extension portion 23 of each extended semiconductor die 22H, 22E, or 22B and the adjacent outer edge (i.e., sidewall) of the encapsulant layer 24 is in a range of about 10 μm to about 50 μm to prevent the extended semiconductor dies 22H, 22E, and 22B from being damaged during a singulation process of the die stack 200.

In some embodiments, thermally conductive features 27 are formed in and penetrate the extended semiconductor dies 22H, 22E, and 22B, as shown in FIG. 2. In some embodiments, thermally conductive features 27 are formed in one or more extension portions 23 of each extended semiconductor die 22H, 22E, or 22B. For example, in the embodiments shown in FIG. 3, the thermally conductive features 27 are formed in opposing extension portions 23 of the extended topmost semiconductor die 22H and are arranged along adjacent sidewalls of the extended topmost semiconductor die 22H (and also arranged along adjacent sidewalls of the encapsulant layer 24). The thermally conductive features 27 within the extended semiconductor dies 22E and 22B may have a similar arrangement as the thermally conductive features 27 within the extended topmost semiconductor die 22H, and thus are not separately shown. In some embodiments, the thermally conductive features 27 are exposed from the top surface of the extended topmost semiconductor die 22H for heat dissipation, as shown in FIG. 3.

In some embodiments, the thermally conductive features 27 include a thermally conductive material, such as a metal (e.g., copper, aluminum) or a metal alloy. Other suitable thermally conductive materials may be used. In some embodiments, the thermally conductive features 27 may be made of the same material as the electrically conductive features 28 (e.g., TSVs) within the same semiconductor die (e.g., 22E or 22B), and they may be formed in the same process as the electrically conductive features 28, although the disclosure is not limited thereto.

In some embodiments, each thermally conductive feature 27 has a circular shape in plan view (as shown in FIG. 3), although other suitable cross-sectional shapes may be used (e.g., square, rectangular, triangular, or other polygonal shapes, not individually shown). In some embodiments, each thermally conductive feature 27 has a cross-sectional size D1 (e.g., diameter) greater than or equal to about 10 μm to facilitate heat dissipation, although smaller sizes may be used. In some embodiments, the thermally conductive feature 27 may be arranged at equal intervals (as shown in FIG. 3), and the spacing S1 between adjacent thermally conductive features 27 may be in a range of about 5 μm to 10 μm, although the thermally conductive feature 27 may be arranged at irregular intervals and with different spacing in other embodiments.

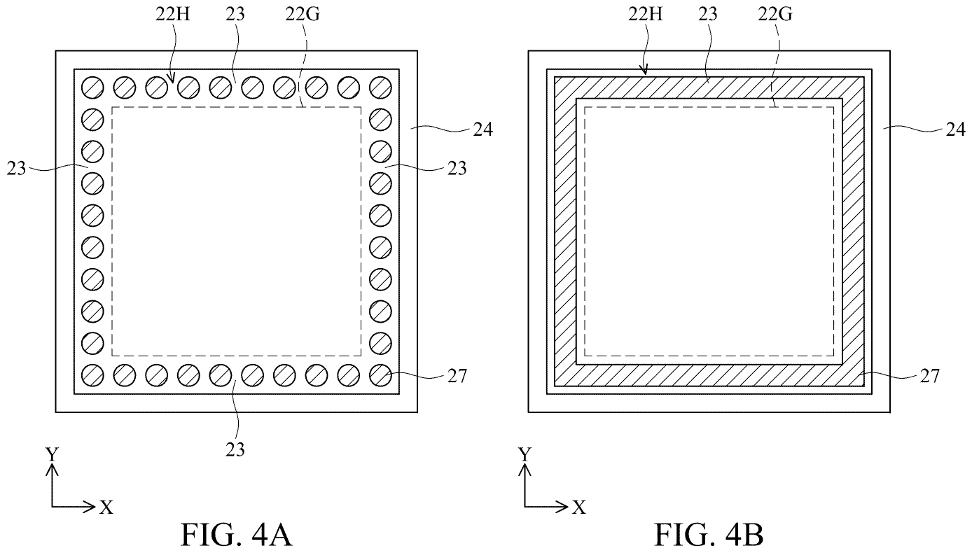

FIGS. 4A and 4B are top views of the die stack 200 shown in FIG. 2, in accordance with some alternative embodiments, showing the extended topmost semiconductor die 22H of the die stack 200 and thermally conductive feature(s) 27 therein. As shown in FIG. 4A, thermally conductive features 27 may be formed in all four extension portions 23 of the extended topmost semiconductor die 22H and penetrate the extended topmost semiconductor die 22H. As shown in FIG. 4B, a single continuous annular thermally conductive feature 27 is formed in the four extension portions 23 of the extended topmost semiconductor die 22H and penetrates the extended topmost semiconductor die 22H. Although not shown, the thermally conductive features 27 within the extended semiconductor dies 22E and 22B may have a similar arrangement as the thermally conductive features 27 within the extended topmost semiconductor die 22H. Many other possible alternative configurations are also included within the scope of this disclosure.

Referring back to FIG. 2, in some embodiments, thermally conductive features 27 may also be formed in and penetrate the bottommost semiconductor die 21. In some embodiments, the thermally conductive features 27 may be formed adjacent to the outer edges (i.e., sidewalls) of the (non-extended) bottommost semiconductor die 21. Although not shown, the thermally conductive features 27 within the bottommost semiconductor die 21 may have a similar arrangement as the thermally conductive features 27 within the extended semiconductor die 22H, 22E, and 22B described above. In some embodiments, each thermally conductive feature 27 within the bottommost semiconductor die 21 and the corresponding overlying thermally conductive features 27 within the extended semiconductor die 22H, 22E, and 22B are arranged in a one-to-one vertical alignment (in the Z-axis direction) (i.e., they overlap vertically in plan view).

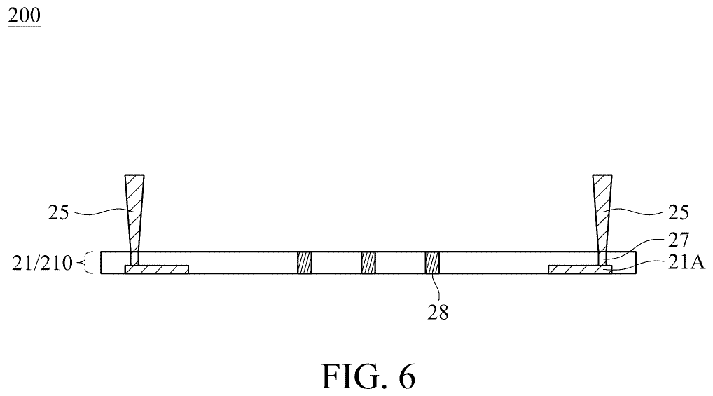

In some embodiments, multiple thermally conductive structures 25 are formed (e.g., embedded) in portions (e.g., side areas) of the encapsulant layer 24 around the non-extended semiconductor dies (e.g., 22G, 22F, 22D, 22C, 22A) to connect the thermally conductive features 27 within the extended semiconductor die 22H, 22E, and 22B and the thermally conductive features 27 within the bottommost semiconductor die 21, as shown in FIG. 2. The sidewalls of thermally conductive structures 25 are substantially vertical, and may (or may not) be slightly sloped depending on different process conditions. The thermally conductive structures 25 are used as through molding vias (TMVs). In some embodiments, the thermally conductive structures 25 include a thermally conductive material similar to that of the thermally conductive features 27, such as a metal (e.g., copper, aluminum) or a metal alloy. Other suitable thermally conductive materials may be used. The formation process of the thermally conductive structures 25 is described below with reference to FIG. 6.

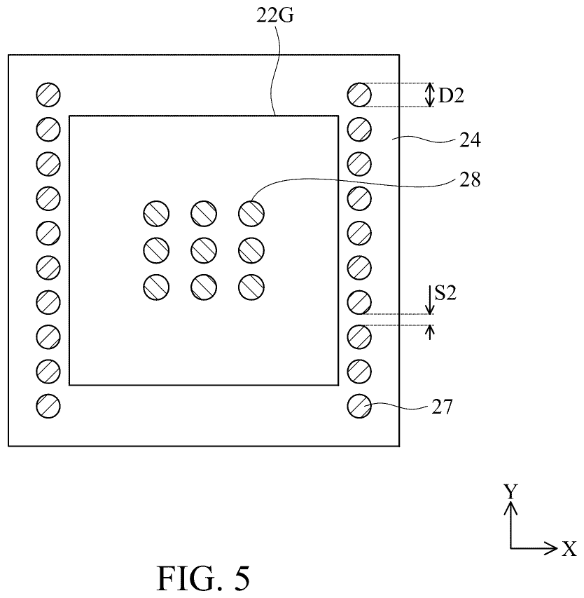

In some embodiments, the thermally conductive structures 25 are located on opposite sides of the non-extended semiconductor dies (e.g., 22G, 22F, 22D, 22C, 22A) (e.g., laterally spaced from these non-extended semiconductor dies) and are arranged along adjacent sidewalls of the encapsulant layer 24, as shown in FIG. 5 (which is a plan view taken along line A-A in FIG. 2 in accordance with some embodiments). In some embodiments, the thermally conductive structures 25 may have a similar cross-sectional shape and arrangement as the thermally conductive features 27 within the extended semiconductor die 22H, 22E, and 22B and the bottommost semiconductor die 21 described above.

In some embodiments, each thermally conductive structure 25 has a circular shape in plan view (as shown in FIG. 5), although other suitable cross-sectional shapes may be used (e.g., square, rectangular, triangular, or other polygonal shapes, not individually shown). In some embodiments, each thermally conductive structure 25 has a cross-sectional size D2 (e.g., diameter) greater than or equal to about 50 μm to facilitate heat dissipation, although smaller sizes may be used. In some embodiments, the thermally conductive structures 25 may be arranged at equal intervals (as shown in FIG. 5), and the spacing S2 between adjacent thermally conductive structures 25 may be in a range of about 5 μm to 10 μm, although the thermally conductive structures 25 may be arranged at irregular intervals and with different spacing in other embodiments. In some embodiments, each thermally conductive structure 25 within the encapsulant layer 24 and the corresponding overlying and underlying thermally conductive features 27 within the extended semiconductor die 22H, 22E, and 22B and the bottommost semiconductor die 21 are arranged in a one-to-one vertical alignment (in the Z-axis direction) (i.e., they overlap vertically in plan view).

With the configuration described above, additional heat dissipation enhancement structures (e.g., including the extension portions 23 of some extended semiconductor dies, the thermally conductive features 27 within the extension portions 23 and the bottommost semiconductor die, and the thermally conductive structures 25 between the thermally conductive features 27) may be formed or placed in the side areas originally occupied by the encapsulant layer 24 to provide additional thermal path in the die stack 200 structure. In some cases, the numerical simulation results show that adding heat dissipation enhancement structures increases the thermal conductivity of the side areas of the encapsulant layer by more than 90 percent, compared with the case without adding heat dissipation enhancement structures.

Also, adding heat dissipation enhancement structures allows more of the heat generated by the lower semiconductor dies to be dissipated through the additional thermal path. For example, some extended semiconductor dies can dissipate heat directly through the additional thermal path. Some non-extended semiconductor dies can transfer heat to adjacent extended semiconductor dies, and then dissipate heat directly through the additional thermal path. Therefore, the heat dissipation efficiency of the entire die stack 200 is improved.

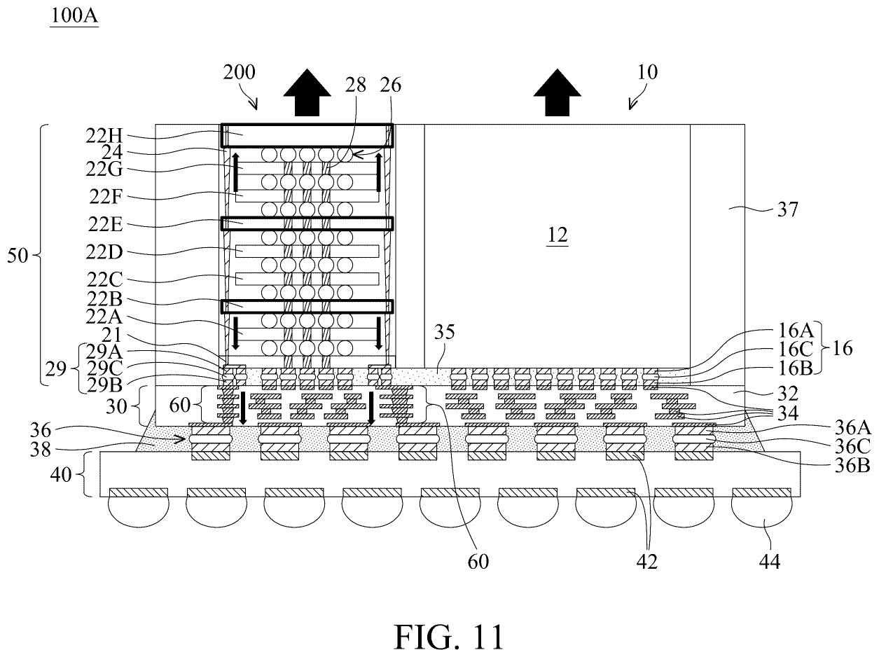

In some embodiments, as shown in FIG. 2, because some thermally conductive features 27 are exposed form the top surface of the topmost semiconductor die 22H, the heat transferred in the additional thermal path can be dissipated to the overlying TIM, package lid, and the heat sink (not shown) through these exposed thermally conductive features 27 (as indicated by the upward arrows in FIG. 2). Additionally, because some thermally conductive features 27 are formed in the bottommost semiconductor die 21, the heat transferred in the additional thermal path can also be dissipated to the underlying components (e.g., the interposer 30 or package substrate 40, see FIG. 11) through these exposed thermally conductive features 27 and the associated thermally conductive bonding structures (e.g., 29, which are described below with reference to FIG. 11) (as indicated by the downward arrows in FIG. 2). Accordingly, it enables heat dissipation from both the top and bottom sides of the die stack 200.

In some embodiments, multiple metal pillar bumps 29A (e.g., formed of copper), which are parts of the thermally conductive bonding structures 29 (see FIG. 11), may be formed over the bottom surface of the bottommost semiconductor die 21 and connected to the thermally conductive features 27 penetrating the bottommost semiconductor die 21, as shown in FIG. 2. In some embodiments, multiple metal pillar bumps 29A may be connected to one thermally conductive feature 27 within the bottommost semiconductor die 21, such as via a large contact pad 21A coupled to the thermally conductive feature 27, which helps improve heat dissipation efficiency. In alternative embodiments, one metal pillar bump 29A is connected to one thermally conductive feature 27 within the bottommost semiconductor die 21, and the contact pad 21A is omitted.

In some embodiments, each metal pillar bump 29A has a cross-sectional size D3 (e.g., diameter, in the X-Y plane) greater than or equal to about 20 μm to facilitate heat dissipation, although smaller sizes may be used. The cross-sectional size D3 may be equal to or different from (e.g., greater than or smaller than) the cross-sectional size D4 of each metal pillar bump 16A over the bottom surface of the bottommost semiconductor die 21. In some embodiments, the metal pillar bumps 29A may be arranged at a pitch P1 such as between about 40 μm and about 80 μm, which may be equal to or different from (e.g., greater than or smaller than) the pitch P2 of the metal pillar bumps 16A.

FIGS. 6 to 10 illustrate cross-sectional views of intermediate steps of forming the die stack 200 shown in FIG. 2, in accordance with some embodiments. In FIG. 6, a semiconductor wafer 210 containing a plurality of identical semiconductor dies 21 is first provided. For simplicity, only one semiconductor die 21 within a package region of the semiconductor wafer 210 is shown, and its internal integrated circuit devices are not shown. In some embodiments, the semiconductor die 21 includes multiple electrically conductive features 28 (e.g., TSVs) formed in a central region thereof and multiple thermally conductive features 27 formed in a peripheral region thereof. The electrically conductive features 28 and the thermally conductive features 27 vertically penetrate through the material (e.g., silicon) of the semiconductor die 21. The electrically conductive features 28 and the thermally conductive features 27 are electrically isolated. In some embodiments, contact pads 21A are formed and exposed at the bottom surface of the semiconductor die 21 and connected to the thermally conductive features 27. The formation process of the semiconductor die 21 is not described in detail here.

Afterwards, thermally conductive structures 25 (e.g., metal vias) are formed over the semiconductor die 21. Each of the thermally conductive structures 25 is connected to one of the exposed thermally conductive features 27. In some embodiments, the thermally conductive structures 25 may have vertical or slightly inclined sidewalls, depending on different process conditions. The extending direction of each thermally conductive structure 25 may be substantially perpendicular to the top surface of the semiconductor die 21. The thermally conductive structures 25 may include a thermally conductive material such as a metal (e.g., copper, aluminum) or metal alloy or another suitable thermally conductive material.

As an example to form the thermally conductive structures 25, a seed layer (not shown) is first formed over the semiconductor die 21. The seed layer is a metal layer, which may be a single layer or a composite layer comprising a plurality of sub-layers formed of different materials. In some embodiments, the seed layer includes a titanium layer and a copper layer over the titanium layer. The seed layer may be formed using, for example, physical vapor deposition (PVD) or the like. A lithography mask is then formed and patterned on the seed layer. The lithography mask may be a photoresist formed by spin coating or the like, and may be exposed to light for patterning. The pattern of the lithography mask corresponds to the thermally conductive structures 25. The patterning forms openings through the lithography mask to expose the seed layer. A thermally conductive material as described above is then formed in the openings of the lithography mask and on the exposed portions of the seed layer. The thermally conductive material may be formed by plating, such as electroless plating or electroplating, or the like. After the thermally conductive material is formed, the lithography mask is removed by an acceptable ashing or stripping process. After the lithography mask is removed, exposed portions of the seed layer may be removed, such as by using an acceptable etching process. The remaining portions of the seed layer and the thermally conductive material form the thermally conductive structures 25. Other suitable formation processes may be used.

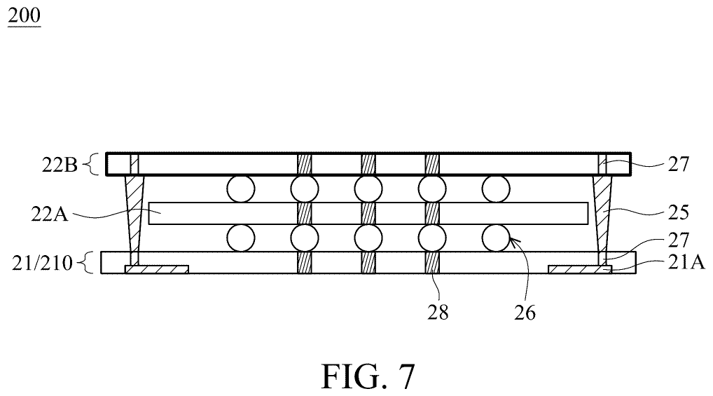

In FIG. 7, a semiconductor die 22A (e.g., a non-extended semiconductor die) is stacked over the semiconductor die 21 using, for example, a pick-and-place tool (not shown). In some embodiments, the semiconductor die 22A is placed between the thermally conductive structures 25. The semiconductor die 22A can be obtained, for example, by sawing or dicing a semiconductor wafer (with several IC dies formed on it) along scribe lines to separate the semiconductor wafer into a plurality of individual semiconductor dies. The semiconductor die 22A is then bonded onto the exposed conductive features (e.g., conductive pads, not shown) of the semiconductor die 21 through electrically conductive structures 26. In some embodiments, the electrically conductive structures 26 may be micro bumps. In some embodiments, some electrically conductive structures 26 are electrically connected to the electrically conductive features 28 (e.g., TSVs) within the semiconductor dies 22A and 21.

Afterwards, a semiconductor die 22B (e.g., an extended semiconductor die) is stacked over the semiconductor die 22A and the thermally conductive structures 25 around the semiconductor die 22A using, for example, a pick-and-place tool (not shown). In some embodiments, the extended semiconductor die 22A includes multiple extension portions 23, and multiple thermally conductive features 27 are formed in and penetrate through the extension portions 23, as described above in FIGS. 2 and 3. In some embodiments, the thermally conductive features 27 may include a thermally conductive material such as a metal (e.g., copper, aluminum) or metal alloy or another suitable thermally conductive material. In some embodiments, the thermally conductive features 27 may be made of the same material as the electrically conductive features 28 (e.g., TSVs) within the same semiconductor die 22B, and they may be formed in the same process as the electrically conductive features 28. The semiconductor die 22B can be obtained, for example, by sawing or dicing another semiconductor wafer (with several IC dies formed on it) along scribe lines to separate the semiconductor wafer into a plurality of individual semiconductor dies, with dummy areas (for the extension portions 23) pre-formed between the functional (or active) region of the each IC die and adjacent scribe lines.

The semiconductor die 22B is then bonded onto the exposed conductive features (e.g., conductive pads, not shown) of the semiconductor die 22A through electrically conductive structures 26. In some embodiments, the electrically conductive structures 26 may be micro bumps. In some embodiments, some electrically conductive structures 26 are electrically connected to the electrically conductive features 28 (e.g., TSVs) within the semiconductor dies 22B and 22A. Meanwhile, the thermally conductive features 27 within the semiconductor die 22B is bonded to the thermally conductive structures 25, for example, through solder bonding or direct metal-to-metal bonding. In the case of solder bonding, solder bumps (e.g., micro bumps, not shown) may be applied between the thermally conductive features 27 and the thermally conductive structures 25 before the bonding process, and may be reflowed with the conductive structures 26 in the same step.

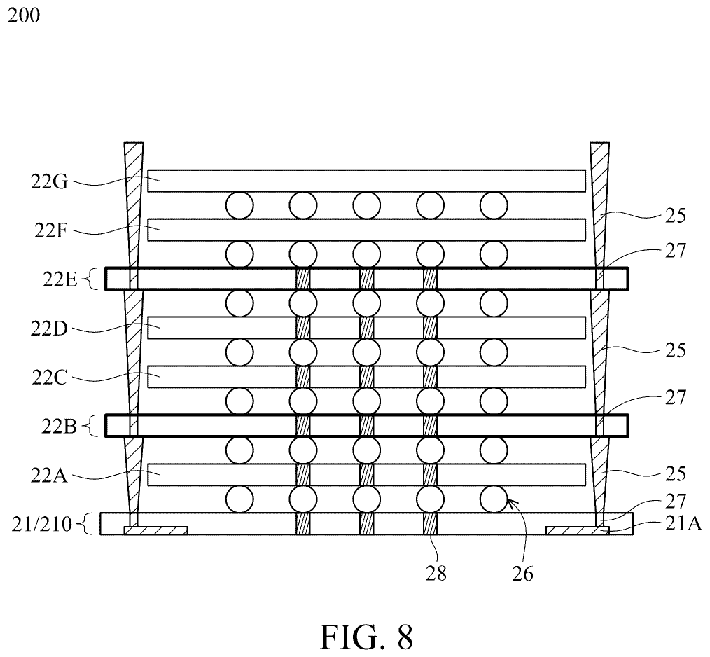

In FIG. 8, more thermally conductive structures 25, non-extended semiconductor dies (e.g., 22C, 22D, 22F, and 22G), and extended semiconductor die (e.g., 22E) may be formed or bonded onto the resulting structure shown in FIG. 7 by repeating similar steps as previously described.

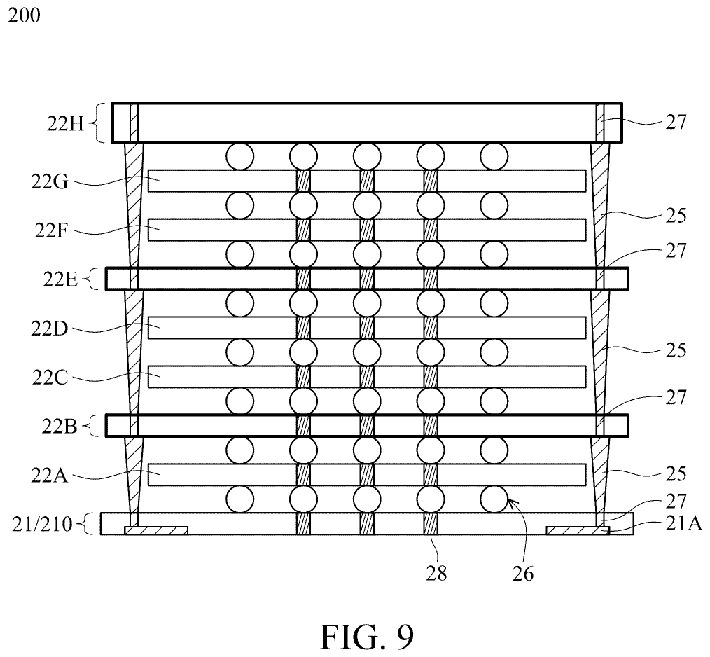

In FIG. 9, an extended topmost semiconductor die 22H is stacked over the resulting structure shown in FIG. 8 using, for example, a pick-and-place tool (not shown). Similarly, multiple thermally conductive features 27 are formed in and penetrate the extension portions 23 of the extended topmost semiconductor die 22H. In some embodiments, the thermally conductive features 27 are exposed from the top surface of the extended topmost semiconductor die 22H. In some embodiments, no electrically conductive features 28 (e.g., TSVs) are formed in the extended topmost semiconductor die 22H. The formation method of the extended topmost semiconductor die 22H may be similar to the formation method of the extended semiconductor die 22B illustrated in FIG. 7.

The extended topmost semiconductor die 22H is then bonded onto the exposed conductive features (e.g., conductive pads, not shown) of the underlying semiconductor die 22G through electrically conductive structures 26 (e.g., micro bumps). In some embodiments, some electrically conductive structures 26 are electrically connected to the electrically conductive features 28 (e.g., TSVs) within the semiconductor dies 22G. Meanwhile, the thermally conductive features 27 within the semiconductor die 22B is bonded to the thermally conductive structures 25 around the semiconductor dies 22G, for example, through solder bonding or direct metal-to-metal bonding.

In some embodiments, after bonding the extended topmost semiconductor die 22H, an underfill element (not shown) is formed (e.g., dispensed) between the semiconductor dies 21, 22A, 22B, 22C, 22D, 22E, 22F, 22G, and 22H to surround and protect the conductive bonding structures 26. In some embodiments, the underfill element is omitted.

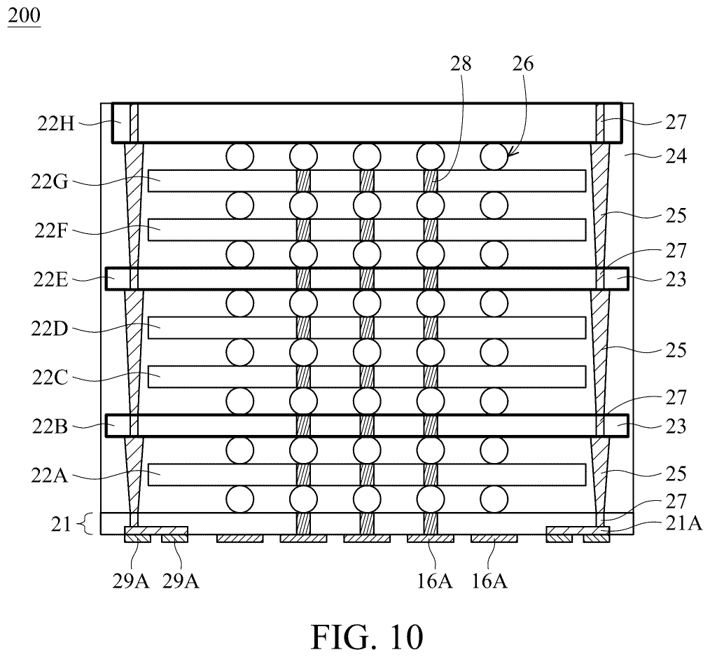

In FIG. 10, an encapsulant layer 24 is formed over the semiconductor die 21 to encapsulate sidewalls of the overlying semiconductor dies 22A-22H, sidewalls of the thermally conductive structures 25, and sidewalls of the underfill elements (if present). In some embodiments, the top surfaces of the extended topmost semiconductor die 22H, the thermally conductive features 27 within the extended topmost semiconductor die 22H, and the encapsulant layer 24 are substantially coplanar such that the top surfaces of the extended topmost semiconductor die 22H and the thermally conductive features 27 therein are exposed. The material and formation method of the encapsulant layer 24 have been described previously, so they are not repeated here.

Metal pillar bumps 16A and 29A are then formed over the bottom surface of the bottommost semiconductor die 21, with the metal pillar bumps 16A electrically coupled to its internal electrically conductive features, and the metal pillar bumps 29A thermal physically coupled to its internal thermally conductive features (e.g., thermally conductive feature 27 and contact pads 21A). In some embodiments, the metal pillar bumps 29A are electrically isolated from the metal pillar bumps 16A.

Additional processing may be performed to complete formation of the die stack 200. For example, a singulation process may be performed on the resulting structure shown in FIG. 10 to form the die stack 200. The singulation process may include sawing along scribe line regions (not illustrated), e.g., between the package region of the semiconductor wafer 210 and adjacent package regions, to singulate the package region from the adjacent package regions. The stacked semiconductor dies and the various components in the package region described above form a die stack 200.

FIG. 11 is a cross-sectional view of an integrated circuit (IC) package 100A, in accordance with some embodiments. The IC package 100A is similar to the IC package 100 shown in FIG. 1, except that the die stack 20 is replaced by the die stack 200 shown in FIG. 2. As shown in FIG. 11, the die stack 200 is bonded onto the interposer 30 through the electrically conductive bonding structures 16 described above and through thermally conductive bonding structures 29. In some embodiments, the thermally conductive bonding structures 29 include solder bumps, metal pillar bumps, other suitable structures, or a combination thereof. In some embodiments, the thermally conductive bonding structures 29 may be similar to the electrically conductive bonding structures 16. For example, each of the thermally conductive bonding structures 29 includes a metal pillar bump 29A, a metal pillar bump 29B, and a solder element 29C, as shown in IFG. 11. The materials and formation methods of the thermally conductive bonding structures 29 may be similar to the materials and formation methods of the electrically conductive bonding structures 16 described above.

As noted above, placing or forming additional heat dissipation enhancement structures in the side areas originally occupied by the encapsulant layer 24 provides an additional thermal path in the die stack 200 structure. This allows more of the heat generated by the lower semiconductor dies within the die stack 200 to be dissipated through the additional thermal path. For example, in some embodiments, the heat generated by some lower semiconductor dies may be dissipated through the additional thermal path to the TIM, package lid, and the heat sink (not shown) located above the topmost semiconductor die 22H (as indicated by the smaller upward arrows in the die stack 200 in FIG. 11). Also, the heat generated by some lower semiconductor dies may be dissipated through the additional thermal path to the interposer 30 below the die stack 200 (as indicated by the smaller downward arrows in the die stack 200 in FIG. 11). Therefore, the problem of heat accumulation in the die stack can be reduced.

In some embodiments, one or more thermally conductive paths 60 may also be formed in the interposer 30 and connected to the thermally conductive bonding structures 29 to help transfer heat from the die stack 200 to the bottom of the interposer 30, as shown in FIG. 11. The heat can then also be dissipated form the interposer 30 via the package substrate 40 to the environment. This helps improve the efficiency of heat dissipation from the underside of the die stack 200. In some embodiments, each of the thermally conductive paths 60 include alternative layers of thermally conductive plates and vias stacked together. The fabrication of the thermally conductive plates and vias may be integrated with the fabrication of the conductive features 34 within the dielectric layers 32 of the interposer 30.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

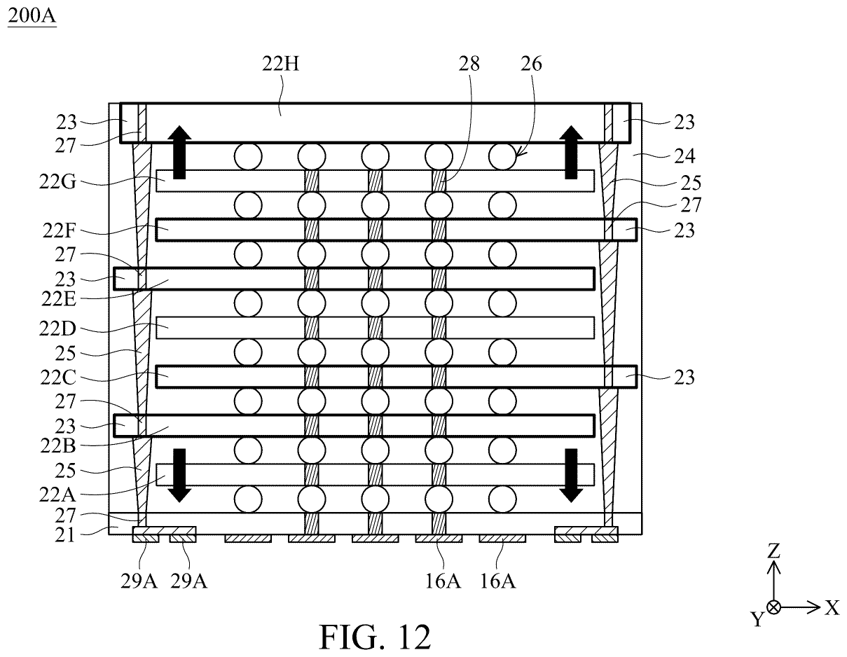

FIG. 12 is a cross-sectional view of a die stack 200A with additional heat dissipation enhancement structures, in accordance with some embodiments. The structure of the die stack 200A is similar to the structure of the die stack 200 shown in FIG. 2, so only the differences will be described below. In the embodiments shown in FIG. 12, more semiconductor dies are extended in size, including the semiconductor dies 22H, 22F, 22E, 22C, and 22B (these semiconductor dies are therefore referred to below as extended semiconductor dies). For example, with the exception of the extended topmost semiconductor die 22H, the remaining extended semiconductor dies (e.g., 22F, 22E, 22C, and 22B) each have an extension portion 23 extending horizontally and outwardly from only one side thereof (e.g., toward the X-direction or -X-direction shown in FIG. 12). Furthermore, adjacent extended semiconductor dies are arranged in a staggered manner. For example, the adjacent extended semiconductor dies 22F and 22E (or 22C and 22B) have extension portions 23 extending in opposite directions (i.e., the X-direction or −X-direction).

With the above configuration, more semiconductor dies can be directly connected to the additional heat dissipation enhancement structures placed in the side areas originally occupied by the encapsulant layer 24. This helps increase the heat dissipation efficiency of the entire die stack 200A.

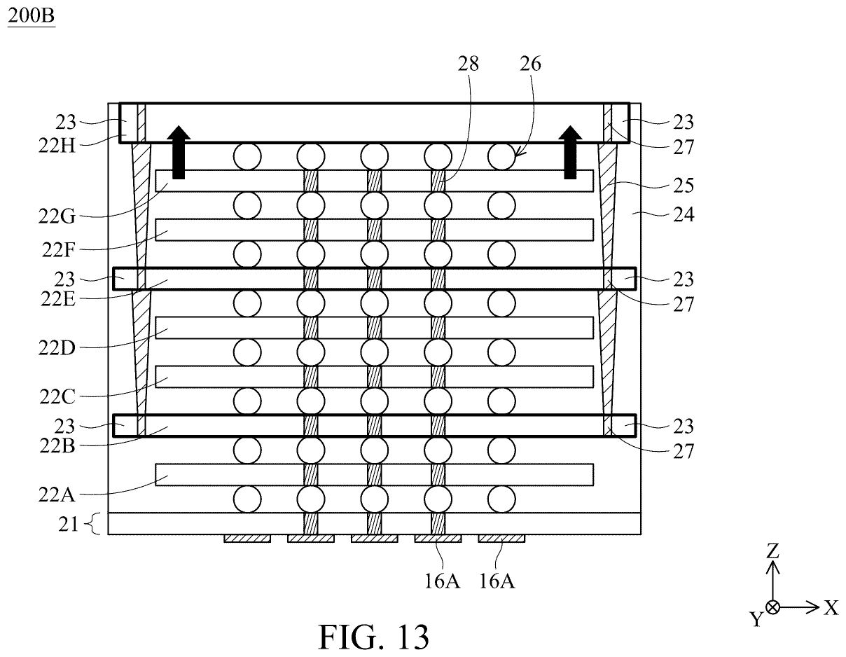

FIG. 13 is a cross-sectional view of a die stack 200B with additional heat dissipation enhancement structures, in accordance with some embodiments. The die stack 200B is similar to the die stack 200 shown in FIG. 2, except that some thermally conductive structures 25 connected to the bottommost semiconductor die 21, the thermally conductive features 27 within the bottommost semiconductor die 21, and the metal pillar bumps 29A over the bottom surface of bottommost semiconductor die 21 are omitted. Other parts of the additional heat dissipation enhancement structures mentioned above are still remain. Therefore, the heat generated by some lower semiconductor dies can also be dissipated through the additional thermal path provided by the additional heat dissipation enhancement structures, such as to the TIM, package lid, and the heat sink (not shown) located above the topmost semiconductor die 22H (as indicated by the upward arrows in the die stack 200B in FIG. 13).

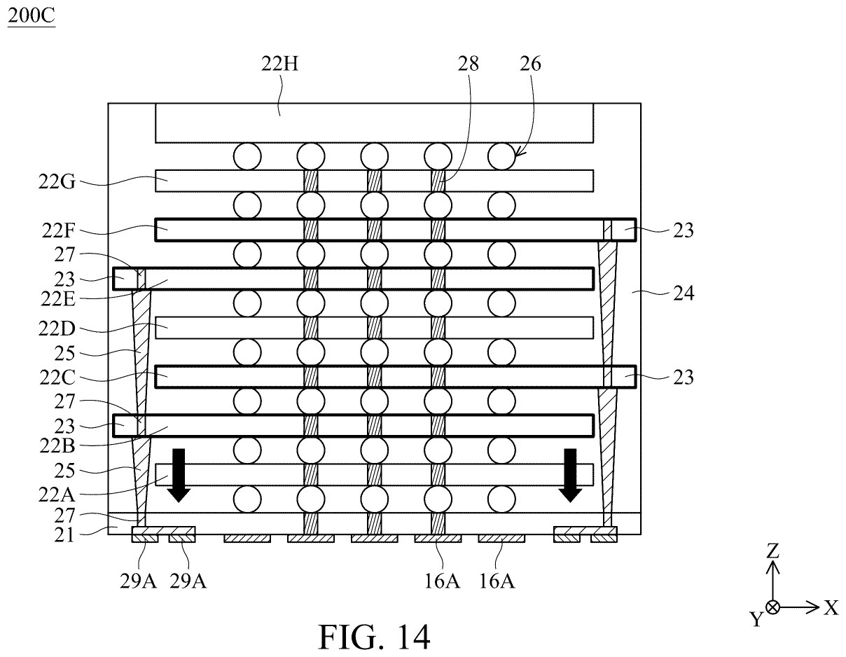

FIG. 14 is a cross-sectional view of a die stack 200C with additional heat dissipation enhancement structures, in accordance with some embodiments. The die stack 200C is similar to the die stack 200A shown in FIG. 12, except that some thermally conductive structures 25 connected to the topmost semiconductor die 22H are omitted and the topmost semiconductor die 22H adopts a non-extended semiconductor die (i.e., without extension portions 23 and embedded thermally conductive features 27). Other parts of the additional heat dissipation enhancement structures mentioned above are still remain. Therefore, the heat generated by some lower semiconductor dies can also be dissipated through the additional thermal path provided by the additional heat dissipation enhancement structures, such as to the components below the die stack (e.g., the interposer 30 and/or package substrate 40, see FIG. 11) (as indicated by the downward arrows in the die stack 200C in FIG. 14).

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, the number of semiconductor dies within a die stack can vary based on actual needs. For example, the positions of the extended semiconductor dies can vary in different embodiments. For example, the extension portions of multiple extended semiconductor dies may all extend in the same single direction, in some other embodiments. For example, all semiconductor dies (e.g., 22A-22H shown in the figures) within the die stack may be extended, such as extending horizontally outward from one or more sides of each die, in some other embodiments. Furthermore, various features in the above-mentioned different embodiments can be combined arbitrarily.

In summary, the embodiments of the present disclosure have some advantageous features. Disposing additional heat dissipation enhancement structures in the side areas originally occupied by the encapsulant layer increases the thermal conductivity of the side areas of the encapsulant layer and provides an additional thermal path in the die stack structure, thereby increasing the heat dissipation efficiency of the entire structure. As a result, the problem of heat accumulation in the die stack can be reduced, and the performance of the die stack is also improved.

In accordance with some embodiments, a die stack structure is provided. The die stack structure includes a base semiconductor die. The die stack structure also includes a non-extended semiconductor die, an extended semiconductor die, and an extended top semiconductor die stacked vertically over the base semiconductor die. The extended semiconductor die and the extended top semiconductor die each have at least one extension portion extending horizontally outward from at least one side thereof as compared to the non-extended semiconductor die. The die stack structure also includes an encapsulant layer formed over the base semiconductor die and encapsulating the sidewalls of the non-extended semiconductor die, the extended semiconductor die, and the extended top semiconductor die. The top surface of the extended top semiconductor die is coplanar with the top surface of the encapsulant layer. The die stack structure also includes thermally conductive features formed in the at least one extension portion of the extended semiconductor die and in the at least one extension portion of extended top semiconductor die. In addition, the die stack structure includes at least one thermally conductive structure embedded in the encapsulant layer, extending vertically between the extended semiconductor die and the extended top semiconductor die, and contacting the thermally conductive features.

In accordance with some embodiments, a die stack structure is provided. The die stack structure includes a base semiconductor die. The die stack structure also includes a plurality of semiconductor dies stacked vertically over the base semiconductor die, wherein the semiconductor dies include a first semiconductor die and a second semiconductor die located between the first semiconductor die and the base semiconductor die. The first semiconductor die and the second semiconductor die each have a dummy area adjacent to a sidewall thereof, wherein no electrically conductive features are formed in the dummy area. The die stack structure also includes an encapsulant layer formed over the base semiconductor die and encapsulating the sidewalls of the semiconductor dies. The die stack structure also includes a first thermally conductive through via formed in the dummy area of the first semiconductor die. The die stack structure also includes a second thermally conductive through via formed in the dummy area of the second semiconductor die. In addition, the die stack structure includes a thermally conductive metal via embedded in the encapsulant layer, extending vertically between the first semiconductor die and the second semiconductor die, and contacting the first thermally conductive through via and the second thermally conductive through via.

In accordance with some embodiments, a method of forming a die stack structure is provided. The method includes providing a base semiconductor die. The method also includes vertically stacking a non-extended semiconductor die, an extended semiconductor die, and an extended top semiconductor die over the base semiconductor die. The extended semiconductor die and the extended top semiconductor die each have at least one extension portion extending horizontally outward from at least one side thereof as compared to the non-extended semiconductor die. The method also includes forming thermally conductive features in the at least one extension portion of the extended semiconductor die and in the at least one extension portion of extended top semiconductor die. The method also includes forming at least one thermally conductive structure between the extended semiconductor die and the extended top semiconductor die to contact the thermally conductive features. The method also includes forming an encapsulant layer over the base semiconductor die to encapsulate the sidewalls of the at least one thermally conductive structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A die stack structure, comprising:
a base semiconductor die;
a non-extended semiconductor die, an extended semiconductor die, and an extended top semiconductor die stacked vertically over the base semiconductor die, wherein the extended semiconductor die and the extended top semiconductor die each have at least one extension portion extending horizontally outward from at least one side thereof as compared to the non-extended semiconductor die;
an encapsulant layer formed over the base semiconductor die and encapsulating sidewalls of the non-extended semiconductor die, the extended semiconductor die, and the extended top semiconductor die, wherein a top surface of the extended top semiconductor die is coplanar with a top surface of the encapsulant layer;
thermally conductive features formed in the at least one extension portion of the extended semiconductor die and in the at least one extension portion of extended top semiconductor die; and
at least one thermally conductive structure embedded in the encapsulant layer, extending vertically between the extended semiconductor die and the extended top semiconductor die, and contacting the thermally conductive features.

2. The die stack structure as claimed in claim 1, wherein the thermally conductive features and the at least one thermally conductive structure overlap vertically.

3. The die stack structure as claimed in claim 1, wherein the at least one thermally conductive structure is laterally spaced from the non-extended semiconductor die.

4. The die stack structure as claimed in claim 1, wherein the thermally conductive features comprise at least one first thermally conductive feature vertically penetrate through the at least one extension portion of the extended top semiconductor die and at least one second thermally conductive feature vertically penetrate through the at least one extension portion of the extended semiconductor die,
wherein the at least one first thermally conductive feature is exposed from the top surface of the extended top semiconductor die.

5. The die stack structure as claimed in claim 4, wherein the at least one first thermally conductive feature has a same arrangement as the at least one second thermally conductive feature in a plan view.

6. The die stack structure as claimed in claim 4, wherein the extended top semiconductor die has a plurality of extension portions extending horizontally outward from a plurality of sides thereof, and
wherein the at least one first thermally conductive feature comprises a plurality of first thermally conductive features formed in some or all of the plurality of extension portions.

7. The die stack structure as claimed in claim 4, wherein the extended top semiconductor die has a plurality of extension portions extending horizontally outward from a plurality of sides thereof, and
wherein the at least one first thermally conductive feature comprises a single continuous first thermally conductive feature formed in plurality of extension portions.

8. The die stack structure as claimed in claim 1, wherein the extended top semiconductor die has two extension portions extending horizontally outward from two sides thereof, with two of the thermally conductive features formed in the two extension portions of the extended top semiconductor die,
wherein the extended semiconductor die has an extension portion extending outwardly from a side thereof in a first horizontal direction, with one of the thermally conductive features formed in the extension portion of the extended semiconductor die,
wherein the die stack structure further comprises:
a second extended semiconductor die stacked vertically over and adjacent to the extended semiconductor die, wherein the second extended semiconductor die has a second extension portion extending outwardly from a side thereof in a second horizontal direction opposite to the first horizontal direction, with one of the thermally conductive features formed in the second extension portion of the second extended semiconductor die, and
wherein the at least one thermally conductive structure comprise a first thermally conductive structure contacting the thermally conductive feature within the extended semiconductor die and the thermally conductive feature within one of the two extension portions of the extended top semiconductor die, and a second thermally conductive structure contacting the thermally conductive feature within the second extended semiconductor die and the thermally conductive feature within the other of the two extension portions of the extended top semiconductor die.

9. The die stack structure as claimed in claim 1, further comprising:
at least one second thermally conductive feature formed in the base semiconductor die; and
at least one second thermally conductive structure embedded in the encapsulant layer, extending vertically between the extended semiconductor die and the base semiconductor die, and contacting the at least one second thermally conductive feature within the base semiconductor die and at least one of the thermally conductive features within the extended semiconductor die.

10. The die stack structure as claimed in claim 9, further comprising:
at least one metal bump formed over a bottom surface of the base semiconductor die and contacting the at least one second thermally conductive feature.

11. The die stack structure as claimed in claim 1, wherein the extended semiconductor die includes electrically conductive features formed therein and electrically isolated from the thermally conductive features within the extended semiconductor die.

12. The die stack structure as claimed in claim 1, wherein the thermally conductive features and the at least one thermally conductive structure comprise a metal material.

13. A die stack structure, comprising:
a base semiconductor die;
a plurality of semiconductor dies stacked vertically over the base semiconductor die, wherein the semiconductor dies comprise a first semiconductor die and a second semiconductor die located between the first semiconductor die and the base semiconductor die,
wherein the first semiconductor die and the second semiconductor die each have a dummy area adjacent to a sidewall thereof, and no electrically conductive features are formed in the dummy area;
an encapsulant layer formed over the base semiconductor die and encapsulating sidewalls of the semiconductor dies;
a first thermally conductive through via formed in the dummy area of the first semiconductor die;
a second thermally conductive through via formed in the dummy area of the second semiconductor die; and
a thermally conductive metal via embedded in the encapsulant layer, extending vertically between the first semiconductor die and the second semiconductor die, and contacting the first thermally conductive through via and the second thermally conductive through via.

14. The die stack structure as claimed in claim 13, wherein the first semiconductor die is a topmost one of the plurality of semiconductor dies and exposed from the encapsulant layer,
wherein the first thermally conductive through via is exposed from a top surface of the first semiconductor die.

15. The die stack structure as claimed in claim 13, wherein the semiconductor dies further comprise a third semiconductor die located between the first semiconductor die and the second semiconductor die,
wherein the thermally conductive metal via is laterally spaced from the third semiconductor die and is not thermally connected to the third semiconductor die.

16. The die stack structure as claimed in claim 13, wherein a cross-sectional size of the thermally conductive metal via is larger than a cross-sectional size of the first thermally conductive through via and a cross-sectional size of the second thermally conductive through via.

17. The die stack structure as claimed in claim 13, further comprising:
a third thermally conductive through via formed in the base semiconductor die; and
a second thermally conductive metal via embedded in the encapsulant layer, extending vertically between the second semiconductor die and the base semiconductor die, and contacting the second thermally conductive through via and the third thermally conductive through via.

18. The die stack structure as claimed in claim 17, wherein the semiconductor dies further comprise a third semiconductor die located between the second semiconductor die and the base semiconductor die,
wherein the second thermally conductive metal via is laterally spaced from the third semiconductor die and is not thermally connected to the third semiconductor die.

19. A method of forming a die stack structure, comprising:
providing a base semiconductor die;
vertically stacking a non-extended semiconductor die, an extended semiconductor die, and an extended top semiconductor die over the base semiconductor die, wherein the extended semiconductor die and the extended top semiconductor die each have at least one extension portion extending horizontally outward from at least one side thereof as compared to the non-extended semiconductor die;
forming thermally conductive features in the at least one extension portion of the extended semiconductor die and in the at least one extension portion of extended top semiconductor die;
forming at least one thermally conductive structure between the extended semiconductor die and the extended top semiconductor die to contact the thermally conductive features; and
forming an encapsulant layer over the base semiconductor die to encapsulate sidewalls of the at least one thermally conductive structure.

20. The method as claimed in claim 19, further comprising:
forming second thermally conductive features in the base semiconductor die; and
forming at least one second thermally conductive structure between the extended semiconductor die and the base semiconductor die to contact the thermally conductive features within the extended semiconductor die and the second thermally conductive features.
